(19) United States
(12) Patent Application Publication
(10) Pub. No.: US 2025/0063902 A1
(43) Pub. Date: Feb. 20, 2025

(54) DISPLAY DEVICE AND METHOD OF MANUFACTURING THE SAME

(71) Applicant: Samsung Display Co., Ltd., Yongin-si (KR)

(72) Inventors: SUNGSIK YUN, Yongin-si (KR); HEE-SANG PARK, Yongin-si (KR); JU-YEON SEO, Yongin-si (KR)

(21) Appl. No.: 18/624,671

(22) Filed: Apr. 2, 2024

(30) Foreign Application Priority Data
Aug. 16, 2023 (KR) 10-2023-0107141

(51) Int. Cl. H10K 59/131; H10K 59/12; H10K 59/80

(52) U.S. Cl. CPC H10K 59/131; H10K 59/1201; H10K 59/873

(57) ABSTRACT

A display device including a substrate including a display area, and a non-display area adjacent to the display area, a first dam in the non-display area above the substrate, and a second dam in the non-display area above the substrate, more adjacent to an edge of the non-display area than the first dam, and including a first organic layer above the substrate, and a second organic layer above the first organic layer, and spaced from a first side of the first organic layer facing the first dam.

### CROSS-REFERENCE TO RELATED APPLICATION

The present application claims priority to and the benefit of Korean Patent Application No. 10-2023-0107141, filed on Aug. 16, 2023, in the Korean Intellectual Property Office, the entire disclosure of which is incorporated herein by reference.

### BACKGROUND

### 1. Field

One or more embodiments relate to the display device with a dam in a non-display area and a method of manufacturing the same.

### 2. Description of the Related Art

A display device may include a display area for displaying an image, and a non-display area surrounding the display area. Pixels, which are the minimum units for displaying the image, may be arranged in the display area. Each of the pixels may include a pixel circuit and a light-emitting element connected to the pixel circuit. Fan-out lines for providing signals and voltages to the pixels may be located in the non-display area.

Dams may be formed in the non-display area to prevent or reduce organic and/or inorganic substances from overflowing during the process of forming an encapsulation layer covering the light-emitting element.

### SUMMARY

One or more embodiments provide a display device for preventing corrosion of fan-out lines in a non-display area.

One or more embodiments provide a method of manufacturing the display device.

A display device according to one or more embodiments may include a substrate including a display area, and a non-display area adjacent to the display area, a first dam in the non-display area above the substrate, and a second dam in the non-display area above the substrate, more adjacent to an edge of the non-display area than the first dam, and including a first organic layer above the substrate, and a second organic layer above the first organic layer, and spaced from a first side of the first organic layer facing the first dam.

The first side of the first organic layer and a side of the second organic layer facing the first dam may have a stepped shape.

The second organic layer may contact a second side of the first organic layer opposite the first side.

The display device may further include an insulating structure between the substrate and the first dam, and including a first area contacting the first organic layer, and spaced from the second organic layer, and a second area contacting the first organic layer and the second organic layer.

The display device may further include an opening defined in the insulating structure to expose at least a portion of an upper surface of the substrate, and the first organic layer may fill the opening.

The display device may further include a blocking pattern between the first organic layer and the second organic layer, and protruding from the second dam toward the first dam.

The blocking pattern may be at an edge of the second dam, and may extend along the first side of the first organic layer.

The display device may further include a first power line on the substrate, and overlapping the non-display area, and a second power line on the substrate, overlapping the non-display area, and spaced from the first power line.

The blocking pattern may include a first blocking pattern connected to the first power line, and on a same layer as the first power line, and a second blocking pattern connected to the second power line, and on a same layer as the second power line.

The blocking pattern may include a first blocking pattern connected to the first power line, and on a different layer from the first power line, and a second blocking pattern connected to the second power line, and on a different layer from the second power line.

A low power voltage may be applied to the first power line, and a high-power voltage may be applied to the second power line.

The display device may further include a transistor in the display area, and including an active layer above the substrate, a gate electrode above the active layer, and a source electrode and a drain electrode contacting the active layer, and a connection electrode above the transistor, and connected to the transistor.

The blocking pattern may include a same material as the connection electrode.

The display device may further include a first inorganic encapsulation layer on the first dam, and extending to the first side of the first organic layer, and a second inorganic encapsulation layer on the first inorganic encapsulation layer.

The first inorganic encapsulation layer may contact the second organic layer.

The first inorganic encapsulation layer may be spaced from the second organic layer.

A method of manufacturing a display device according to one or more embodiments may include forming a first dam in a non-display area on a substrate including a display area, and the non-display area adjacent to the display area, forming a first organic layer in the non-display area, and more adjacent to an edge of the non-display area that the first dam, forming a second organic layer on the first organic layer, and spaced from a first side of the first organic layer facing the first dam, and forming a second dam including the first organic layer and the second organic layer.

The first side of the first organic layer and a side of the second organic layer facing the first dam may have a stepped shape.

The method may further include forming a blocking pattern between the first organic layer and the second organic layer and protruding from the second dam toward the first dam.

The method may further include forming a first inorganic encapsulation layer on the first dam and extending to the first side of the first organic layer, and forming a second inorganic encapsulation layer on the first inorganic encapsulation layer.

In a display device and a method of manufacturing the same according to one or more embodiments of the present disclosure, the display device may include a first organic layer in a non-display area and a second organic layer on the first organic layer and having a stepped shape together with a first side of the first organic layer. A portion of an interlayer insulating layer overlapping an edge of the first organic layer facing a first dam may be damaged by an etching process. Because the second organic layer does not cover the first side of the first organic layer, the first organic layer overlapping the second organic layer may not cover a damaged portion of the interlayer insulating layer. Accordingly, a portion where the interlayer insulating layer overlaps the second organic layer is not damaged, so even if the moisture flows in from the outside of a second dam including the first organic layer and the second organic layer through the inflow path, corrosion of fan-out lines may be prevented or reduced.

In addition, because there is no damage to the interlayer insulating layer immediately under the first organic layer, a stress applied to the interlayer insulating layer covering the fan-out lines is reduced, so that the likelihood of a crack occurring inside the display device may be prevented or reduced.

### BRIEF DESCRIPTION OF DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a circuit diagram illustrating a pixel according to one or more embodiments of the present disclosure.

FIG. 3 is a cross-sectional view taken along the line I-I′ in FIG. 1

FIG. 4 is an enlarged plan view of area “A” of FIG. 1 according to one or more embodiments of the present disclosure.

FIG. 5 is a cross-sectional view illustrating an example of a cross-section taken along the line II-II′ in FIG. 4.

FIG. 6 is a cross-sectional view illustrating an example of a cross-section taken along the line III-III′ in FIG. 4.

FIG. 7 is a cross-sectional view illustrating another example in FIG. 5.

FIG. 8 is a cross-sectional view illustrating another example in FIG. 6.

FIGS. 9, 10, 11, 12, 13, 14, 15, and 16 are cross-sectional views illustrating a method of manufacturing the display device of FIGS. 5 and FIG. 6.

FIG. 17 is an enlarged plan view of area “A” of FIG. 1 according to one or more embodiments of the present disclosure.

FIG. 18 is a cross-sectional view taken along the line III-III′ in FIG. 17.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

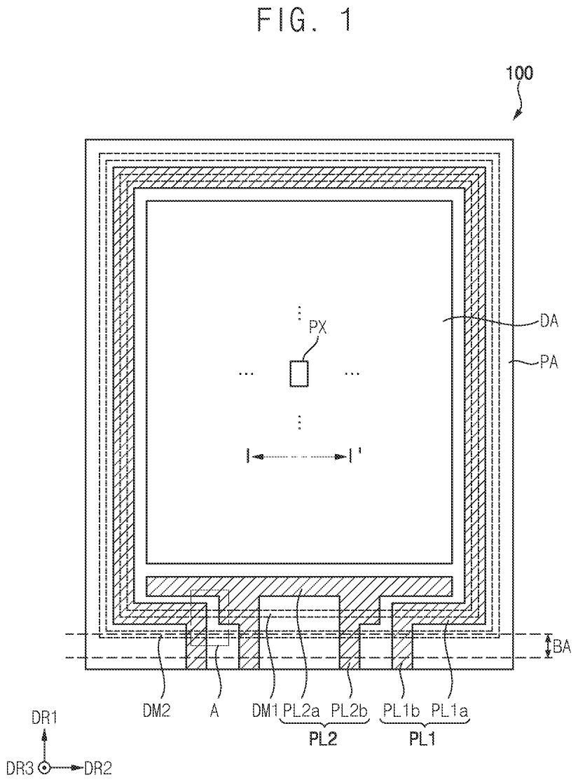

FIG. 1 is a plan view illustrating a display device according to one or more embodiments of the present disclosure.

Referring to FIG. 1, a display device 100 according to one or more embodiments of the present disclosure may include a display area DA and a non-display area PA. The non-display area PA may be adjacent to the display area DA. For example, the non-display area PA may surround the display area DA.

A plurality of pixels PX may be arranged in the display area DA. The pixels PX may be arranged in a matrix form along the first direction DR1, and along the second direction DR2 intersecting the first direction DR1. Each of the pixels PX may emit light having a color (e.g., a preset color). An image may be displayed in the display area DA by the light emitted from each of the pixels PX.

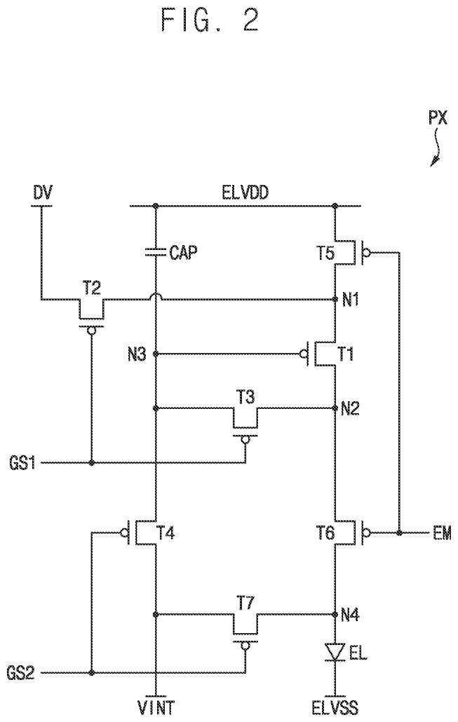

A first power line PL1 and a second power line PL2 may be located in the non-display area PA. The first power line PL1 and the second power line PL2 may supply a power voltage to the pixels PX. For example, the first power line PL1 supplies a low power voltage (e.g., the low power voltage ELVSS in FIG. 2) to the pixels PX, and the second power line PL2 supplies a high-power voltage (for example, the high-power voltage (ELVDD) in FIG. 2) to pixels PX.

The first power line PL1 may include a first portion PL1a surrounding at least a portion of the display area DA, and a second portion PL1b connected to an end of the first portion PL1a and extending in a direction opposite to a first direction DR1. The second portion PL1b may be connected to a first power source, and may transmit the low power voltage to the first portion PL1a.

The second power line PL2 may include a first portion PL2a oriented in a direction opposite to the first direction DR1 from the display area DA and extending along the second direction DR2, and a second portion PL2b connected to the first portion PL2a and extending in a direction opposite to the first direction. The second portion PL2b is connected to a second power source, and may transmit the high-power voltage to the first portion PL2a.

The non-display area PA may include a bending area BA. Some of components of the display device 100 may be bent in the bending area BA. For example, a portion of the second portion PL1b of the first power line PL1 and a portion of the second portion PL2b of the second power line PL2 may be located in the bending area BA and may be bent.

At least one first dam DM1 may be located in the non-display area PA. The first dam DM1 may surround the display area DA (e.g., in plan view). For example, the first dam DM1 may include one dam, or two or more dams spaced apart from each other. That is, the first dam DM1 may include at least one dam.

A second dam DM2 may be located in the non-display area PA. The second dam DM2 may be spaced apart from the first dam DM1, and may surround the first dam DM1. In addition, the second dam DM2 may be closer to an edge of the non-display area PA than the first dam DM1. For example, a portion of the second dam DM2 may be located on the bending area BA. Accordingly, a portion of the second dam DM2 may be bent in the bending area BA.

The first dam DM1 may block organic substances forming an organic encapsulation layer of an encapsulation layer for sealing the display area DA from flowing out of the first dam DM1. The second dam DM2 may prevent or reduce an inorganic encapsulation layer of the encapsulation layer from being formed outside the second dam DM2.

FIG. 2 is a circuit diagram illustrating a pixel according to one or more embodiments of the present disclosure. For example, FIG. 2 may illustrate one of the pixels PX in FIG. 1.

Referring to FIG. 2, the pixel PX according to one or more embodiments of the present disclosure may include a first transistor T1, a second transistor T2, a third transistor T3, a fourth transistor T4, a fifth transistor T5, a sixth transistor T6, a seventh transistor T7, a capacitor CAP, and a light-emitting element EL.

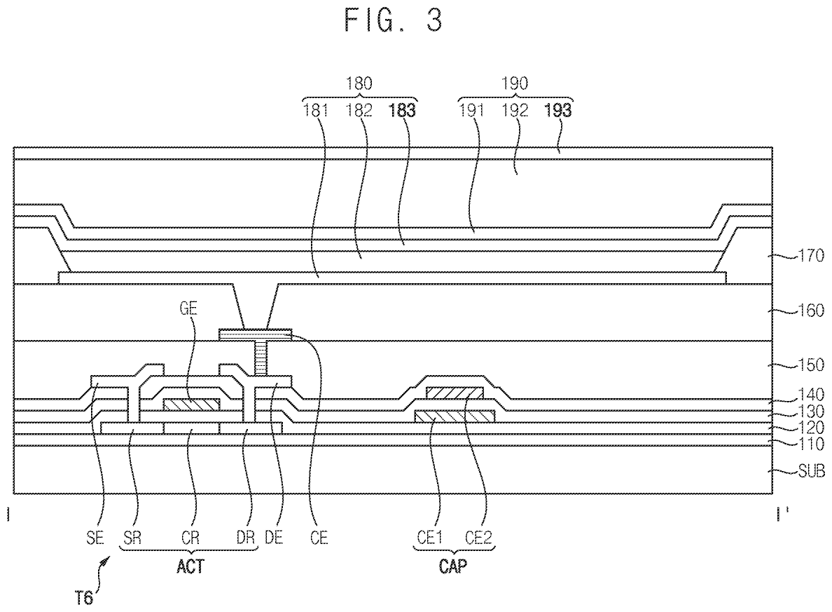

The first transistor T1 may be connected between a first node N1 and a second node N2. The first transistor T1 may include a source electrode (e.g., the source electrode SE in FIG. 3) connected to the first node N1, a drain electrode (e.g., the drain electrode DE in FIG. 3) connected to the second node N2, and a gate electrode (e.g., the gate electrode (GE) in FIG. 3) connected to a third node (N3).

The second transistor T2 may be connected between a data line and the first node N1. The second transistor T2 may include a source electrode for receiving a data voltage DV, a drain electrode connected to the first node N1, and a gate electrode for receiving a first gate signal GS1.

The third transistor T3 may be connected between the second node N2 and the third node N3. The third transistor T3 may include a source electrode connected to the third node N3, a drain electrode connected to the second node N2, and a gate electrode for receiving the first gate signal GS1.

The fourth transistor T4 may be connected between an initialization voltage line and the third node N3. The fourth transistor T4 may include a source electrode for receiving the initialization voltage VINT, a drain electrode connected to the third node N3, and a gate electrode for receiving a second gate signal GS2.

The fifth transistor T5 may be connected between the second power that provides the high-power voltage ELVDD and the first node N1. The fifth transistor T5 may include a source electrode for receiving the high-power voltage ELVDD, a drain electrode connected to the first node N1, and a gate electrode for receiving an emission control signal EM.

The sixth transistor T6 may be connected between the second node N2 and a fourth node N4. The sixth transistor T6 may include a source electrode connected to the second node N2, a drain electrode connected to the fourth node N4, and a gate electrode for receiving the emission control signal EM.

The seventh transistor T7 may be connected between the initialization voltage line and the fourth node N4. The seventh transistor T7 may include a source electrode for receiving the initialization voltage VINT, a drain electrode connected to the fourth node N4, and a gate electrode for receiving the second gate signal GS2.

The capacitor CAP may be connected between the second power source and the third node N3. The capacitor CAP may include a first capacitor electrode (e.g., the first capacitor electrode CE1 in FIG. 3) connected to the third node N3, and a second capacitor electrode (e.g., the second capacitor electrode CE2 in FIG. 3) for receiving the high-power voltage ELVDD.

The light-emitting element EL may be connected between the fourth node N4 and the first power providing the low power voltage ELVSS. The low power voltage ELVSS may be lower than the high-power voltage ELVDD. The light-emitting device EL may include a first electrode connected to the fourth node N4 and a second electrode for receiving the low power voltage ELVSS.

In one or more embodiments, one or more of the first, second, third, fourth, fifth, sixth, and seventh transistors T1, T2, T3, T4, T5, T6, and T7 may be a PMOS transistor. However, the embodiments of the present disclosure are not limited thereto, and in one or more other embodiments, one or more of the first, second, third, fourth, fifth, sixth, and seventh transistors T1, T2, T3, T4, T5, T6, and T7 may not be an NMOS (n-channel metal-oxide-silicon) transistor or CMOS (complementary metal-oxide-silicon) transistor.

In FIG. 2, one of the pixels PX may be shown as including seven transistors and one capacitor, but embodiments of the present disclosure are not limited thereto. For example, the pixel PX may include 2 to 6, or 8 or more transistors, and may include two or more capacitors.

FIG. 3 is a cross-sectional view taken along the line I-l′ in FIG. 1

Referring to FIGS. 1, 2, and 3, the display device 100 may include a substrate SUB, a buffer layer 110, an active pattern ACT, a first gate-insulating layer 120, a first gate pattern, a second gate-insulating layer 130, a second gate pattern, a interlayer insulating layer 140, a first data pattern, a first flattening (e.g., planarizing) layer 150, a second data pattern, a second flattening layer 160, a pixel-defining layer 170, a light-emitting element 180, and a encapsulation layer 190.

The substrate SUB may be a transparent insulating substrate. For example, the substrate SUB may include glass, quartz, plastic, and the like. These may be used alone or in combination with each other.

The buffer layer 110 may be located on the substrate SUB. The buffer layer 110 may prevent or reduce impurities from diffusing from the substrate SUB to the active pattern ACT.

The buffer layer 110 may include an inorganic insulating material. The inorganic insulating material may include silicon nitride (SiNx), silicon oxide (SiOx), silicon oxynitride (SiOxNy), and the like. These may be used alone or in combination.

The active pattern ACT may be located on the buffer layer 110. The active pattern ACT may include amorphous silicon, polycrystalline silicon, or an oxide semiconductor. The active pattern ACT may include a source region SR and a drain region DR doped with impurities, and a channel region CR positioned between the source region SR and the drain region DR.

The first gate-insulating layer 120 may be located on the buffer layer 110. The first gate-insulating layer 120 may cover the active pattern ACT on the buffer layer 110. For example, the first gate-insulating layer 120 may have a substantially uniform thickness along a profile of the active pattern ACT. Alternatively, the first gate-insulating layer 120 may sufficiently cover the active pattern ACT and may have a substantially flat upper surface without creating a step around the active pattern ACT.

The first gate-insulating layer 120 may include an inorganic insulating material. The inorganic insulating material may include silicon nitride, silicon oxide, silicon oxynitride, and the like. These may be used alone or in combination.

The first gate pattern may be located on the first gate-insulating layer 120. The first gate pattern may include a gate electrode GE and a first capacitor electrode CE1. The gate electrode GE may overlap the channel region CR of the active pattern ACT.

The first gate pattern may include metal, alloy, conductive metal oxide, conductive metal nitride, transparent conductive material, and the like. These may be used alone or in combination. For example, the first gate pattern may include molybdenum.

The second gate-insulating layer 130 may be located on the first gate-insulating layer 120. The second gate-insulating layer 130 may cover the first gate pattern on the first gate-insulating layer 120. For example, the second gate-insulating layer 130 may have a substantially uniform thickness along a profile of the first gate pattern. Alternatively, the second gate-insulating layer 130 may sufficiently cover the first gate pattern and may have a substantially flat upper surface without creating a step around the first gate pattern.

The second gate-insulating layer 130 may include an inorganic insulating material. The inorganic insulating material may include silicon nitride, silicon oxide, or silicon oxynitride, and the like. These may be used alone or in combination.

The second gate pattern may be located on the second gate-insulating layer 130. The second gate pattern may include a second capacitor electrode CE2 and the initialization voltage line. The second capacitor electrode CE2 may overlap the first capacitor electrode CE1.

The second gate pattern may include metal, alloy, conductive metal oxide, conductive metal nitride, transparent conductive material, and the like. These may be used alone or in combination. For example, the second gate pattern may include molybdenum Mo.

Accordingly, the second capacitor electrode CE2 may form a capacitor CAP together with the first capacitor electrode CE1.

The interlayer insulating layer 140 may be located on the second gate-insulating layer 130. The interlayer insulating layer 140 may cover the second gate pattern on the second gate-insulating layer 130. For example, the interlayer insulating layer 140 may have a substantially uniform thickness along a profile of the second gate pattern. Alternatively, the interlayer insulating layer 140 may sufficiently cover the second gate pattern, and may have a substantially flat upper surface without creating a step around the second gate pattern.

The interlayer insulating layer 140 may include an inorganic insulating material. The inorganic insulating material may include silicon nitride, silicon oxide, silicon oxynitride, and the like. These may be used alone or in combination.

The first data pattern may be located on the interlayer insulating layer 140. The first data pattern may include a source electrode SE and a drain electrode DE. The source electrode SE and drain electrode DE may be connected to the source region SR and drain region DR of the active pattern ACT, respectively.

The first data pattern may include metal, alloy, conductive metal oxide, conductive metal nitride, transparent conductive material, and the like. These may be used alone or in combination. For example, the first data pattern may include aluminum and titanium.

Accordingly, the active pattern ACT, the gate electrode GE, the source electrode SE, and the drain electrode DE may form a transistor. For example, the transistor may correspond to the sixth transistor T6 in FIG. 3.

The first flattening layer 150 may be located on the interlayer insulating layer 140. The first flattening layer 150 may cover the first data pattern on the interlayer insulating layer 140. For example, the first flattening layer 150 may not create a step around the first data pattern and may have a substantially flat upper surface. The first flattening layer 150 may include an organic insulating material, such as polyimide. However, embodiments of the present disclosure may not be limited thereto.

The second data pattern may be located on the first flattening layer 150. The second data pattern may include a connection electrode CE and the data line. The connection electrode CE may be connected to the drain electrode DE, or to the source electrode SE.

The second data pattern may include metal, alloy, conductive metal oxide, conductive metal nitride, transparent conductive material, and the like. These may be used alone or in combination. For example, the second data pattern may include aluminum and titanium.

The second flattening layer 160 may be located on the first flattening layer 150. The second flattening layer 160 may cover the second data pattern on the first flattening layer 150. For example, the second flattening layer 160 may not create a step around the second data pattern, and may have a substantially flat upper surface. The second flattening layer 160 may include an organic insulating material, such as polyimide.

The light-emitting element 180 may include a first electrode 181, a light-emitting layer 182, and a second electrode 183.

The first electrode 181 may be located on the second flattening layer 160. The first electrode 181 may be connected to the connection electrode CE. The first electrode 181 may include metal, alloy, conductive metal oxide, conductive metal nitride, transparent conductive material, and the like. These may be used alone or in combination. For example, the first electrode 181 may include silver and indium tin oxide (ITO).

The pixel-defining layer 170 may be located on the second flattening layer 160. The pixel-defining layer 170 may partially cover the first electrode 181 on the second flattening layer 160. In addition, an opening that exposes at least a portion of the first electrode 181 may be defined in the pixel-defining layer 170. For example, the opening of the pixel-defining layer 170 may expose a central portion of the first electrode 181, and the pixel-defining layer 170 may cover an edge of the first electrode 181. The pixel-defining layer 170 may include an organic insulating material, such as polyimide.

The light-emitting layer 182 may be located on the first electrode 181 exposed by the opening of the pixel-defining layer 170. For example, the light-emitting layer 182 may include an organic light-emitting material and quantum dots. For example, the organic light-emitting material may include a low molecular weight organic compound or a high molecular weight organic compound. The second electrode 183 may be located on the light-emitting layer 182. In addition, the second electrode 183 may be located on the pixel-defining layer 170. The second electrode 183 may include metal, alloy, conductive metal oxide, conductive metal nitride, transparent conductive material, and the like. For example, the second electrode 183 may include aluminum, platinum, silver, magnesium, gold, chromium, tungsten, titanium, and the like. These may be used alone or in combination.

The encapsulation layer 190 may cover the light-emitting element 180. The encapsulation layer 190 may seal the display area DA, and may protect the light-emitting element 180 from external impurities.

The encapsulation layer 190 may include at least one inorganic encapsulation layer and at least one organic encapsulation layer. For example, the encapsulation layer 190 may include a first inorganic encapsulation layer 191, a second inorganic encapsulation layer 193 located on (e.g., above) the first inorganic encapsulation layer 191, and an organic encapsulation layer 192 positioned between the first inorganic encapsulation layer 191 and the second inorganic encapsulation layer 193.

The first inorganic encapsulation layer 191 may be located on the second electrode 183. The first inorganic encapsulation layer 191 may have a substantially uniform thickness along a profile of the second electrode 183.

The organic encapsulation layer 192 may be located on the first inorganic encapsulation layer 191. The organic encapsulation layer 192 may not create steps around the first inorganic encapsulation layer 191 and may have a substantially flat upper surface.

The second inorganic encapsulation layer 193 may be located on the organic encapsulation layer 192. The second inorganic encapsulation layer 193 may have a substantially uniform thickness and a substantially flat upper surface.

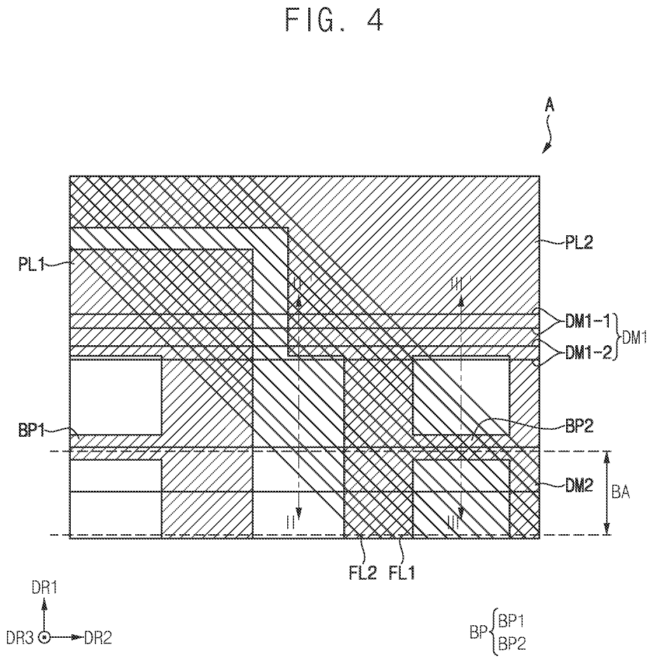

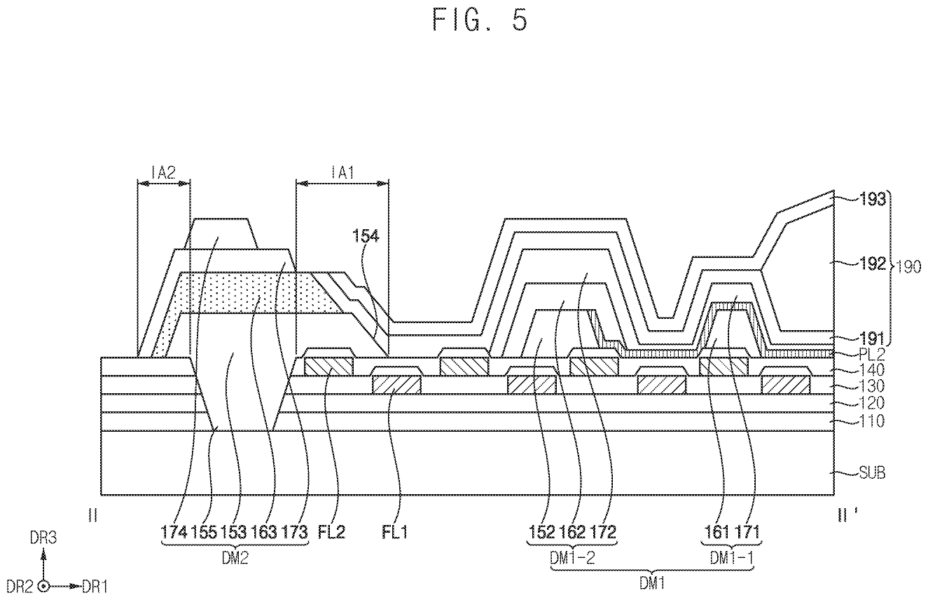

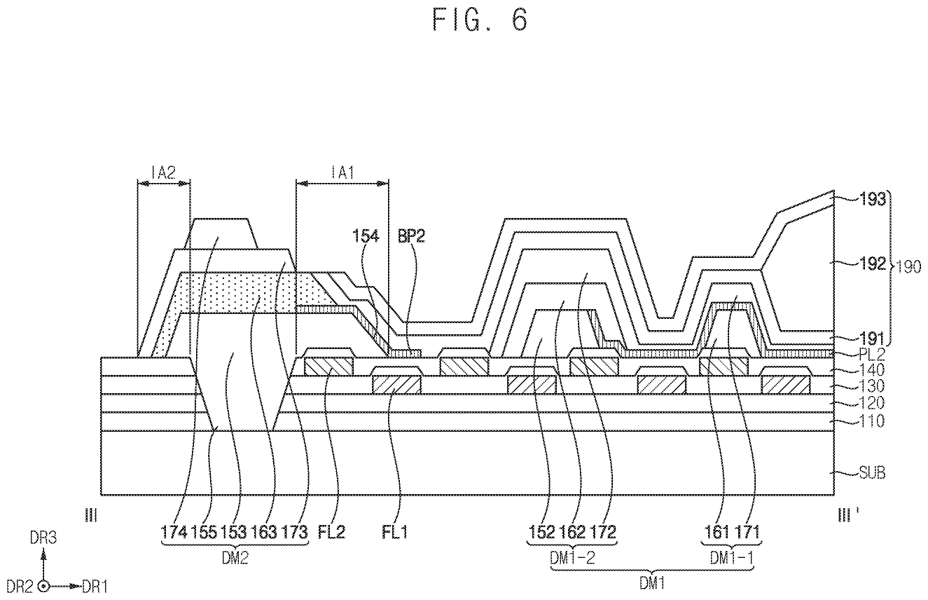

FIG. 4 is an enlarged plan view of area “A” of FIG. 1 according to one or more embodiments of the present disclosure. FIG. 5 is a cross-sectional view illustrating an example of a cross-section taken along the line II-II′ in FIG. 4. FIG. 6 is a cross-sectional view illustrating an example of a cross-section taken along the line III-III′ in FIG. 4.

Referring to FIGS. 1, 4, and 5, the display device 100 may include the substrate SUB, the buffer layer 110, the first gate-insulating layer 120, the second gate-insulating layer 130, first fan-out lines FL1, second fan-out lines FL2, the interlayer insulating layer 140, a first power line PL1, a second power line PL2, a blocking pattern BP, the first dam DM1, the second dam DM2, and the encapsulation layer 190.

The buffer layer 110 may be located on the substrate SUB. The first gate-insulating layer 120 may be located on the buffer layer 110. The second gate-insulating layer 130 may be located on the first gate-insulating layer 120.

The first fan-out lines FL1 may be located on the same layer as the first gate pattern, and may include the same material. For example, the first fan-out lines FL1 may be formed through the same process as the first gate pattern. In addition, the second fan-out lines FL2 may be located on the same layer as the second gate pattern, and may include the same material. For example, the second fan-out lines FL2 may be formed through the same process as the second gate pattern.

Each of the first fan-out lines FL1 and the second fan-out lines FL2 may extend in a first diagonal direction between the first direction DR1 and a direction opposite to the second direction DR2. In addition, the first fan-out lines FL1 and the second fan-out lines FL2 may not overlap each other in a plane view. For example, the first fan-out lines FL1 and the second fan-out lines FL2 adjacent to each other may be arranged to be spaced apart from each other in a second diagonal direction perpendicular to the first diagonal direction.

As shown in FIG. 5, the interlayer insulating layer 140 may be located on the second gate-insulating layer 130. A (1-1)th dam DM1-1 and a (1-2)th dam DM1-2 may be located on the interlayer insulating layer 140.

An insulating structure may be defined as a structure including the buffer layer 110, the first gate-insulating layer 120, the second gate-insulating layer 130, and the interlayer insulating layer 140. The insulating structure may include a first area IA1 and a second area IA2.

An opening 155 exposing at least a portion of the upper surface of the substrate SUB may be defined in the insulating structure. The first area IA1 may be an area located in the first direction DR1 from the opening 155. In addition, the second area IA2 may be an area located in a direction opposite to the first direction DR1 from the opening 155.

The first power line PL1 and the second power line PL2 may be located on the interlayer insulating layer 140. Each of the first power line PL1 and the second power line PL2 may be located on a same layer as either the first data pattern or the second data pattern, and may include the same material. In one or more embodiments, the first power line PL1 and the second power line PL2 may each be located on the same layer as the second data pattern, and include a same material.

The first dam DM1 may include the (1-1)th dam DM1-1 and the (1-2)th dam DM1-2. FIGS. 4 and 5 show that the first dam DM1 includes two dams, but embodiments of the present disclosure may not be limited thereto. For example, the first dam DM1 may include at least one dam.

The (1-1)th dam DM1-1 may surround the display area DA. The (1-2)th dam DM1-2 may be spaced apart from the (1-1)th dam DM-1, and may surround the (1-1)th dam DM-1.

The second dam DM2 may be spaced apart from the first dam DM1, and may surround the first dam DM1 on a plane. For example, the second dam DM2 may be spaced apart from the first dam DM1-2, and may surround the first dam DM1-2.

The (1-1)th dam DM1-1 may include a first sub-layer 161 and a second sub-layer 171 located on the first sub-layer 161. The first sub-layer 161 may include substantially the same material as the second flattening layer 160. The second sub-layer 171 may include substantially the same material as the pixel-defining layer 170.

The (1-2)th dam DM1-2 may include a first sub-layer 152, a second sub-layer 162 located on the first sub-layer 152, and a third sub-layer 172 located on the second sub-layer 162. The first sub-layer 152 may include substantially the same material as the first flattening layer 150. The second sub-layer 162 may include substantially the same material as the second flattening layer 160. The third sub-layer 172 may include substantially the same material as the pixel-defining layer 170.

The second dam DM2 may include a first organic layer 153, a second organic layer 163 located on the first organic layer 153, a third organic layer 173 located on the second organic layer 163, and a fourth organic layer 174 located on the third organic layer 173.

The first organic layer 153 may include substantially the same material as the first flattening layer 150. In one or more embodiments, the first organic layer 153 may fill the opening 155 of the insulating structure. For example, the first organic layer 153 may contact a portion of the upper surface of the substrate SUB exposed by the opening 155, and may extend to a portion of the upper surface of the interlayer insulating layer 140.

The second organic layer 163 may include substantially the same material as the second flattening layer 160. The second organic layer 163 may be spaced apart from the first side 154 of the first organic layer 153 facing in the first direction DR1. For example, the second organic layer 163 may not contact the first side 154 of the first organic layer 153, and may not contact a portion of the interlayer insulating layer 140 adjacent to the first area IA1. In one or more embodiments, the first side 154 of the first organic layer 153 may have a stepped shape along with the side of the second organic layer 163 facing the first dam DM1.

An edge of the second dam DM2 facing the first dam DM1 may contact the first area IA1 through the first organic layer 153. In this case, the second organic layer 163 of the second dam DM2 may not contact the first area IA1.

The second organic layer 163 may contact a second side (e.g., left side in FIG. 5) surface of the first organic layer 153 facing in a direction opposite to the first direction DR1. For example, the second organic layer 163 may cover the second side of the first organic layer 153, and may contact the second area IA2.

The third organic layer 173 may contact one side of the second organic layer 163, and may not contact the other side. For example, the third organic layer 173 may contact one side of the second organic layer 163 facing away from the first dam DM1. In addition, the third organic layer 173 may contact the other side of the second organic layer 163 facing in a direction opposite to the first direction DR1.

The third organic layer 173 may include substantially the same material as the pixel-defining layer 170. In addition, the fourth organic layer 174 may include substantially the same material as the third organic layer 173. For example, the fourth organic layer 174 may be formed through the same process as the third organic layer 173, or may be formed through a separate process from the third organic layer 173.

The encapsulation layer 190 may include the first inorganic encapsulation layer 191, the organic encapsulation layer 192, and the second inorganic encapsulation layer 193. The encapsulation layer 190 may be located on the interlayer insulating layer 140. The encapsulation layer 190 may cover at least a portion of the first dam DM1 and the second dam DM2 on the interlayer insulating layer 140.

An edge of the organic encapsulation layer 192 may be located on the first dam DM1. For example, the edge of the organic encapsulation layer 192 may be positioned to overlap an edge of the first dam DM1 facing in the first direction DR1. For example, the edge of the organic encapsulation layer 192 may be closer to the display area DA than the edge of the first dam DM1 adjacent to the second dam DM2. Accordingly, the first dam DM1 may prevent or reduce the organic matter of the organic encapsulation layer 192 from overflowing to the outside of the first dam DM1.

An edge of the encapsulation layer 190 may be located on the second dam DM2. For example, an edge of the first inorganic encapsulation layer 191 and an edge of the second inorganic encapsulation layer 193 may be located on the second dam DM2 (e.g., on a portion of the second dam DM2). Accordingly, the second dam DM2 may prevent or reduce the first inorganic encapsulation layer 191 and the second inorganic encapsulation layer 193 from forming in an area (e.g., the area of the second dam DM2 facing a direction opposite to the first direction DR1) outside of the second dam DM2.

Because the edge of the organic encapsulation layer 192 is located on, or adjacent to, the first dam DM1, the first inorganic encapsulation layer 191 and the second inorganic encapsulation layer 193 of the encapsulation layer 190 may be located between the first dam DM1 and the second dam DM2. For example, the organic encapsulation layer 192 of the encapsulation layer 190 may not be located between the first dam DM1 and the second dam DM2.

In one or more embodiments, the first inorganic encapsulation layer 191 may contact the first organic layer 153 and the second organic layer 163. In addition, the first inorganic encapsulation layer 191 may overlap the first area IA1. For example, the first inorganic encapsulation layer 191 may contact the first side 154 of the first organic layer 153 facing the first dam DM1, and the side of the second organic layer 163 facing the first dam DM1. Referring further to FIG. 6, the blocking pattern BP may include a first blocking pattern BP1 and a second blocking pattern BP2.

The first blocking pattern BP1 may be connected to the first power line PL1. In addition, the second blocking pattern BP2 may be connected to the second power line PL2.

The first blocking pattern BP1 may be connected to the first power line PL1. In addition, the second blocking pattern BP2 may be connected to the second power line PL2.

In one or more embodiments, the second blocking pattern BP2 may be located on the same layer as the second power line PL2, and may include the same material. For example, the second blocking pattern BP2 may be formed through the same process as the second power line PL2. The second blocking pattern BP2 may extend between the first organic layer 153 and the second organic layer 163 along the first side 154 of the first organic layer 153.

In one or more embodiments, the first blocking pattern BP1 may be located on the same layer as the first power line PL1. That is, the first blocking pattern BP1 may be formed through the same process as the first power line PL1. For example, the first blocking pattern BP1 may be located on the interlayer insulating layer 140, and may contact a lower portion of the first organic layer 153. For example, the first blocking pattern BP1 may be positioned under the second blocking pattern BP2 shown in FIG. 6.

In one or more embodiments, the first blocking pattern BP1 may include substantially the same material as the first data pattern. For example, the first blocking pattern BP1 may include aluminum and titanium.

In one or more embodiments, the second blocking pattern BP2 may include substantially the same material as the second data pattern. For example, the second blocking pattern BP2 may include aluminum and titanium.

If the first blocking pattern BP1 is not connected to the first power line PL1, static electricity may be generated in the first blocking pattern BP1, and the display device (e.g., the display device in FIG. 1) may be damaged. However, because the first blocking pattern BP1 is connected to the first power line PL1 for transmitting the low power voltage ELVSS, static electricity may not be generated in the blocking pattern BP. In addition, because the second blocking pattern BP2 is connected to the second power line PL2 for transmitting the high-power voltage ELVDD, static electricity may not be generated, and may be substantially the same as the first blocking pattern BP1 described above.

The second blocking pattern BP2 may be located on the interlayer insulating layer 140, and may extend to a point between the first organic layer 153 and the second organic layer 163 along the first side 154 of the first organic layer 153. In this case, the second blocking pattern BP2 may overlap the first area IA1 of the insulating structure.

Although only the second blocking pattern BP2 is shown in FIG. 6, a position of the first blocking pattern BP1 may also be substantially equal to a position of the second blocking pattern. For example, in one or more embodiments, a cross-sectional view cut along an imaginary line passing through both the first power line PL1, and the first blocking pattern BP1 may have substantially the same location and structure as the cross-sectional view of FIG. 6.

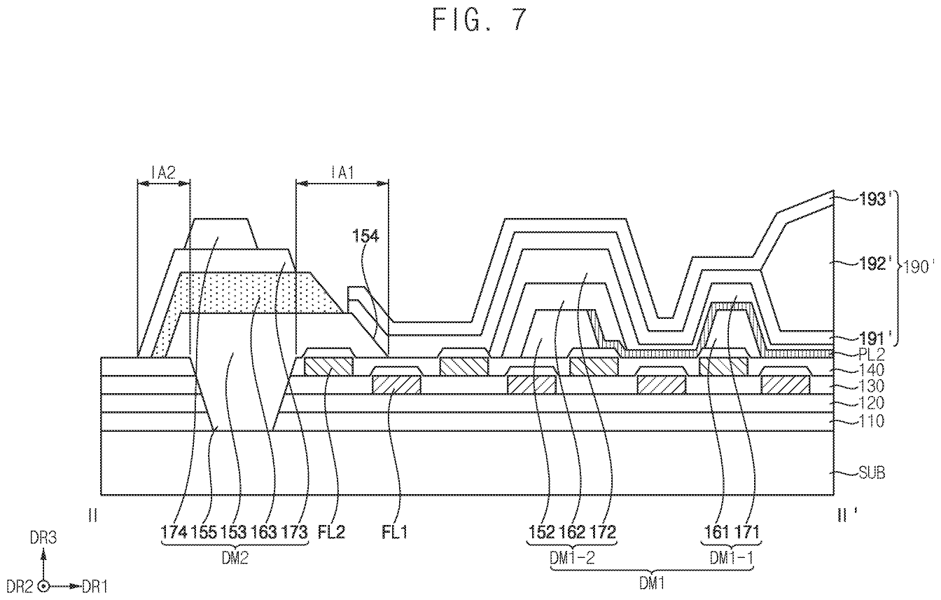

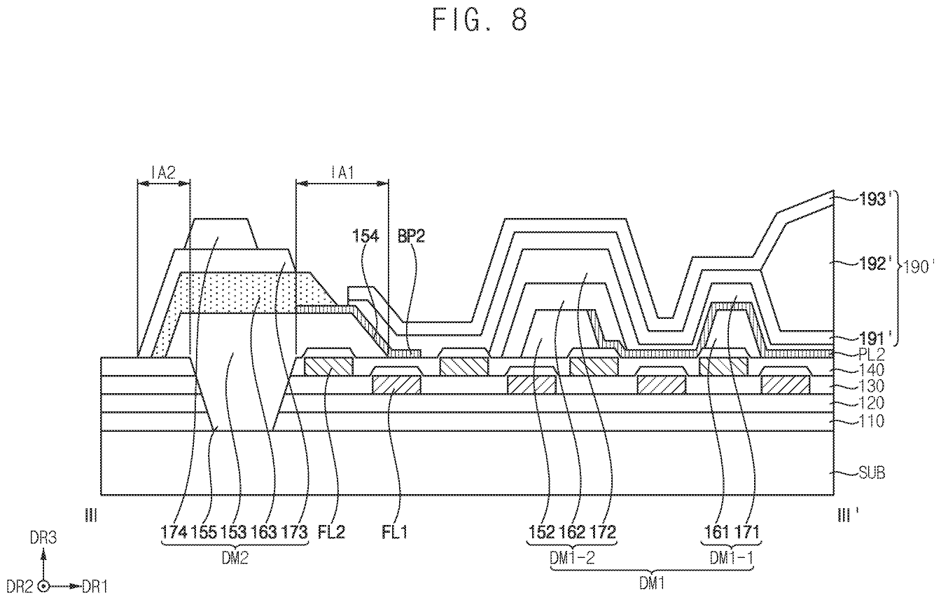

FIG. 7 is a cross-sectional view illustrating another example in FIG. 5. For example, FIG. 7 is a cross-sectional view taken along the line II-II′ in FIG. 4 according to one or more other embodiments of the display device (e.g., the display device 100 in FIG. 1). FIG. 8 is a cross-sectional view illustrating another example in FIG. 6.

Hereinafter, descriptions that overlap with the components of the display device 100 described with reference to FIGS. 5 and 6 will be omitted or simplified.

Referring to FIGS. 7 and 8, a first inorganic encapsulation layer 191′ and a second inorganic encapsulation layer 193′ may be located on the first organic layer 153. In one or more embodiments, the first inorganic encapsulation layer 191′ and the second inorganic encapsulation layer 193′ may be spaced apart from the second organic layer 163. For example, the first inorganic encapsulation layer 191′ and the second inorganic encapsulation layer 193′ may contact the first organic layer 153 along the first side 154 of the first organic layer 153, while not contacting the second organic layer 163. For example, a portion where the first inorganic encapsulation layer 191′ and the second inorganic encapsulation layer 193′ contact the second dam DM2 may be the first organic layer 153.

As described above, a portion of the second dam DM may be located in the bending area BA. The encapsulation layer 190 may not cover an upper portion of each of the first organic layer 153 and the second organic layer 163 within the bending area BA. Accordingly, a moisture inflow path may occur in a portion where the encapsulation layer 190 does not cover the upper portion of each of the first organic layer 153 and the second organic layer 163.

Meanwhile, a portion of the interlayer insulating layer 140 overlapping the edge of the first organic layer 153 facing the first dam DM may be damaged by an etching process. In this case, because the second organic layer 163 does not cover the first side 154 of the first organic layer 153, the first organic layer 153 overlapping the second organic layer 163 may not cover the damaged portion of interlayer insulating layer 140.

Accordingly, a portion of the interlayer insulating layer 140 overlapping the second organic layer 163 may not be damaged, so even if the moisture flows from the outside of the second dam DM2 through the inflow path, corrosion of the fan-out lines FL may be prevented or reduced.

In addition, the portion of the interlayer insulating layer 140 overlapping the second organic layer 163 may not be damaged, so a stress applied to the interlayer insulating layer 140 covering the fan-out lines FL may be decreased. Therefore, cracks occurring inside the display device 100 may be prevented or reduced.

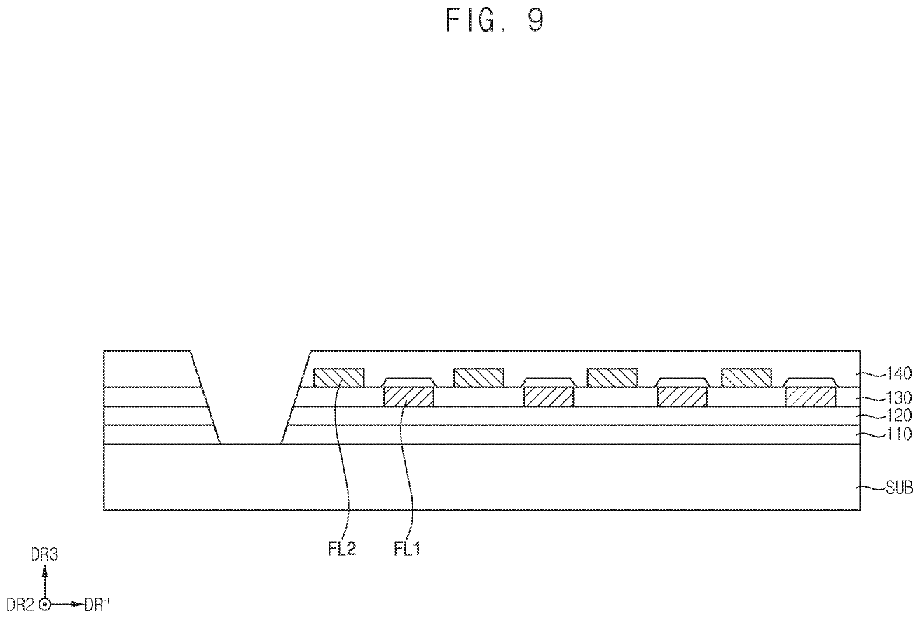

FIGS. 9, 10, 11, 12, 13, 14, 15, and 16 is cross-sectional views illustrating a method of manufacturing the display device of FIGS. 5 and FIG. 6.

Referring to FIG. 9, the insulating structure (e.g., the buffer layer 110, the first gate-insulating layer 120, the second gate-insulating layer 130, and the interlayer insulating layer 140 in FIG. 6), the first fan-out lines FL1, and second fan-out lines FL2 may be formed. In addition, the opening (e.g., the opening 155 in FIG. 5) may be defined in the insulating structure, so that at least a portion of the upper surface of the substrate SUB may be exposed.

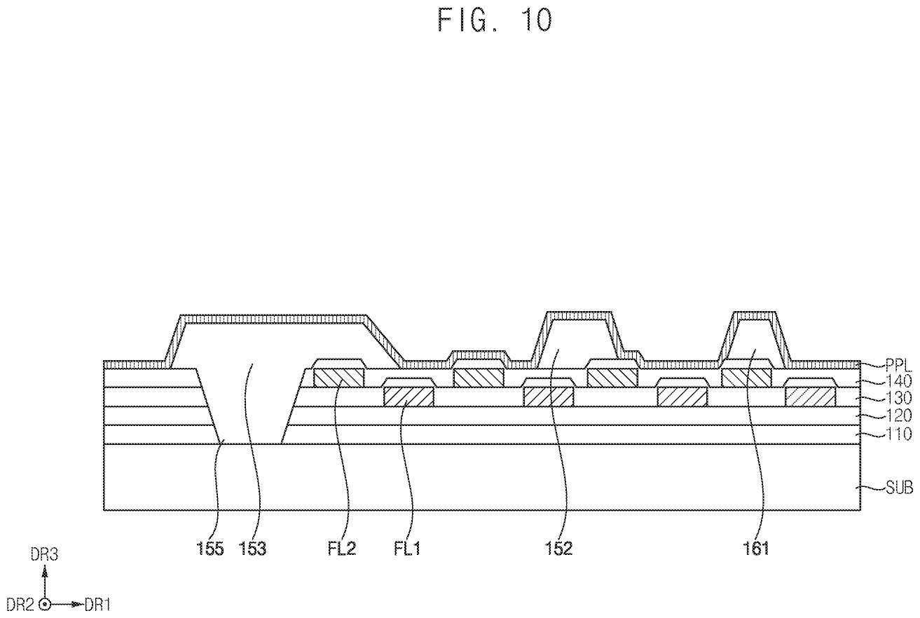

Referring to FIG. 10, the first organic layer 153 may be formed in the opening 155. In addition, the first sub-layer 161 of the (1-1)th dam DM1-1 and the first sub-layer 152 of the (1-2)th dam DM1-2 may be formed on the insulating structure. Afterwards, a preliminary power line PPL is formed on the first organic layer 153, the first sub-layer 161 of the (1-1)th dam DM1-1, the first sub-layer 152 of the (1-2)th dam DM1-2, and the interlayer insulating layer 140. For example, the preliminary power line PPL may contact the first organic layer 153, the first sub-layer 161 of the (1-1)th dam DM1-1, the first sub-layer 152 of the (1-2)th dam DM1-2, and the interlayer insulating layer 140.

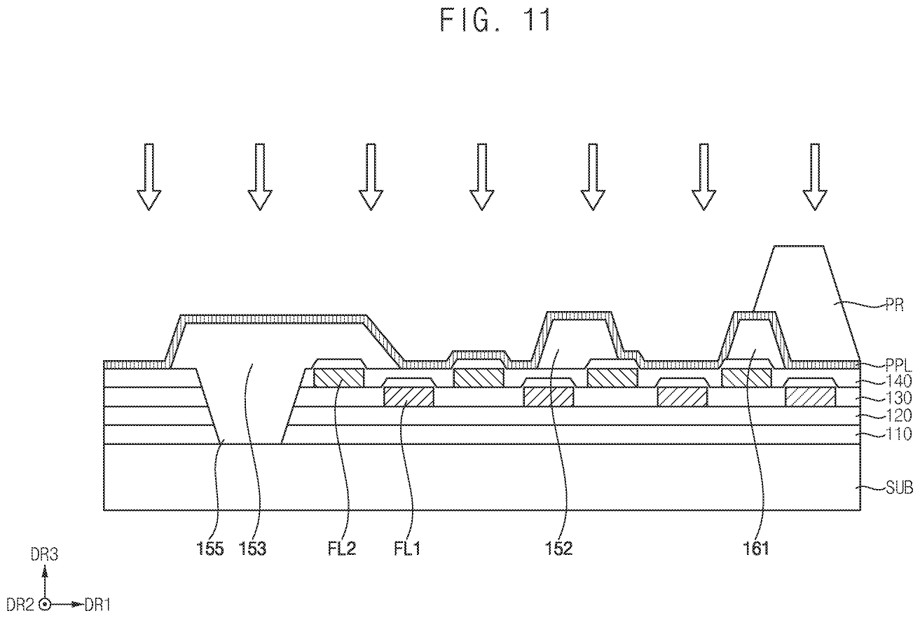

Referring to FIG. 11, a photosensitive layer PR may be formed on a portion of the preliminary power line PPL adjacent to the first sub-layer 161 of the (1-1)th dam DM1-1. A portion of the preliminary power line PPL that is not located under the photosensitive layer PR may be removed through an etching process.

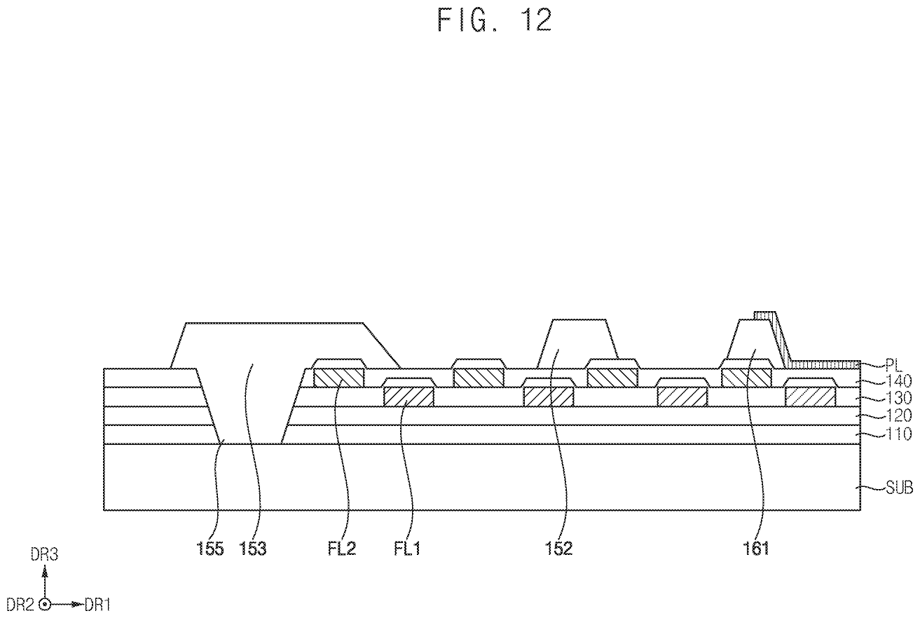

Referring to FIG. 12, the power line PL may be formed on the interlayer insulating layer 140 through the etching process. The power line PL may be a portion of the preliminary power line PPL that has not been removed through the etching process. For example, the power line PL may cover a portion of the first sub-layer 161 of the (1-1)th dam DM1-1. In addition, the interlayer insulating layer 140 may be thinner than the interlayer insulating layer 140 in FIG. 9 through the etching process.

In one or more embodiments, the power line PL may cover the first sub-layer 152 of the (1-2)th dam DM1-2 along the first sub-layer 161 of the (1-1)th dam DM1-1. For example, as shown in FIGS. 5, 6, 7, and 8, the power line PL may cover a portion of the first sub-layer 152 of the (1-2)th dam DM1-2.

The power line PL may be either the first power line PL1 or the second power line PL2 in FIG. 4.

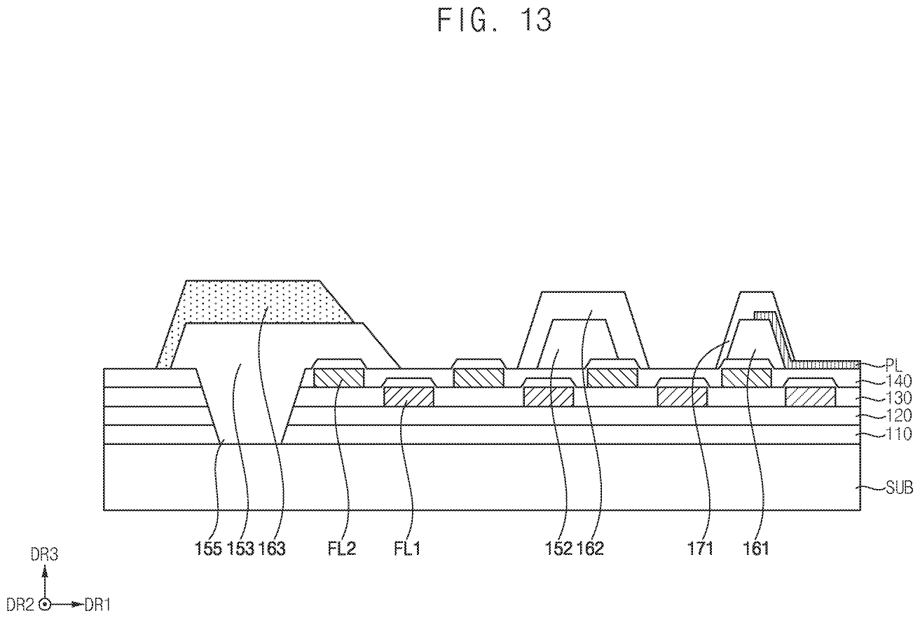

Referring to FIG. 13, the second organic layer 163 may be formed on the first organic layer 153. In addition, the second sub-layer 171 of the (1-1)th dam DM1-1 and the second sub-layer 162 of the (1-2)th dam DM1-2 may be formed. After a manufacturing process in FIGS. 9, 10, 11, 12, and 13, the first inorganic encapsulation layer 191 and the second inorganic encapsulation layer 193 may cover the first organic layer 153, a portion of the second organic layer 163, the first dam DM1, and the interlayer insulating layer 140.

Accordingly, the display device 100 in FIG. 5 may be manufactured.

As described above, through the etching process, an upper portion of the interlayer insulating layer 140 adjacent to the first fan-out lines FL1 may become thin, and a portion of the interlayer insulating layer 140 may be damaged. According to the manufacturing method of the display device 100, the damaged portion of the interlayer insulating layer 140 may not be covered with the second organic layer 163. Accordingly, according to the etching process, a moisture may not flow into the damaged portion of the interlayer insulating layer 140 and the upper portion of the interlayer insulating layer 140 adjacent to the damaged portion, a corrosion may be prevented or reduced from occurring in the first and second fan-out lines FL1 and FL2.

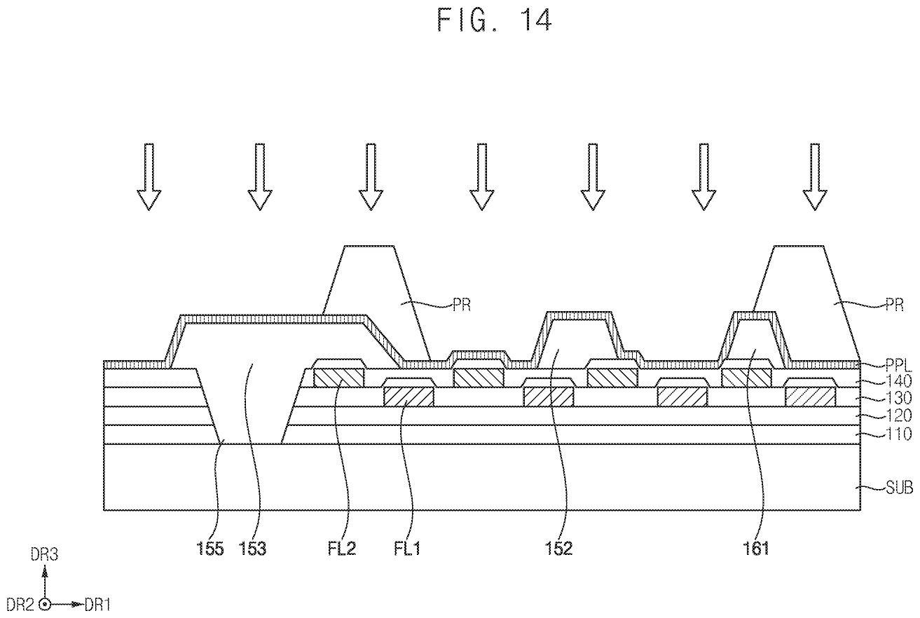

Referring to FIGS. 14, 15, and 16 are cross-sectional views showing the process of forming an area including the blocking pattern BP. Hereinafter, descriptions that overlap with the components of the manufacturing method described with reference to FIGS. 9, 10, 11, 12, and 13 will be omitted or simplified.

Referring to FIG. 14, in the process of FIG. 11, the photosensitive layer PR may be formed in an area adjacent to the edge of the second dam DM2 facing the first dam DM1. A portion of the preliminary power line PPL that is not located under the photosensitive layer PR may be removed through an etching process.

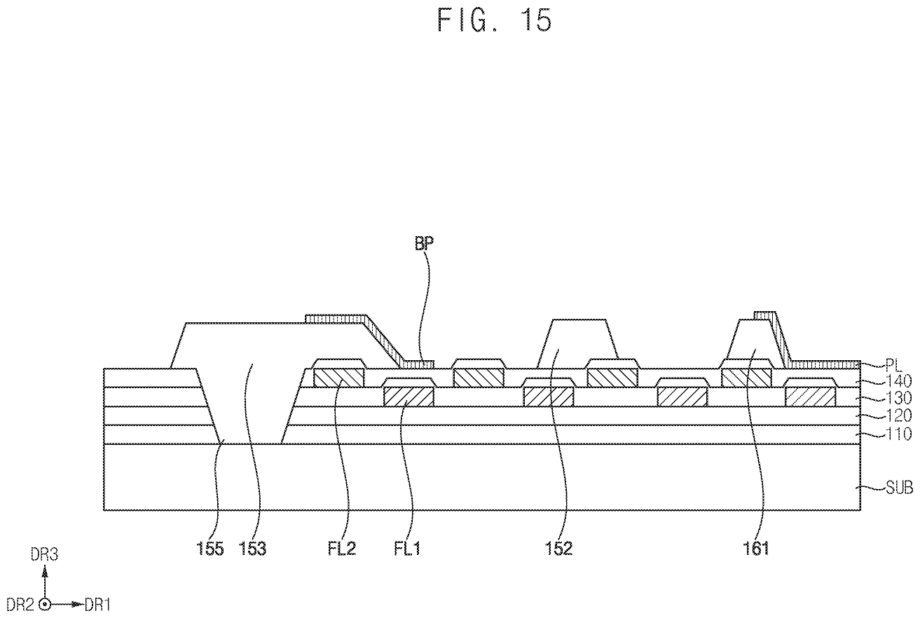

Referring to FIG. 15, the power line PL and the blocking pattern BP may be formed on the interlayer insulating layer 140 through the etching process. For example, the power line PL may cover the first sub-layer 161 of the (1-1)th dam DM1-1. In addition, the blocking pattern BP may cover a portion of the second dam DM2.

The power line PL and the blocking pattern BP may include the same material. For example, the power line PL may be formed through the same process as the blocking pattern BP. In addition, the blocking pattern BP may be one of the first blocking pattern BP1 or the second blocking pattern BP2 in FIG. 4.

In one or more embodiments, the power line PL may cover the first sub-layer 152 of the (1-2)th dam DM1-2 along the first sub-layer 161 of the (1-1)th dam DM1-1.

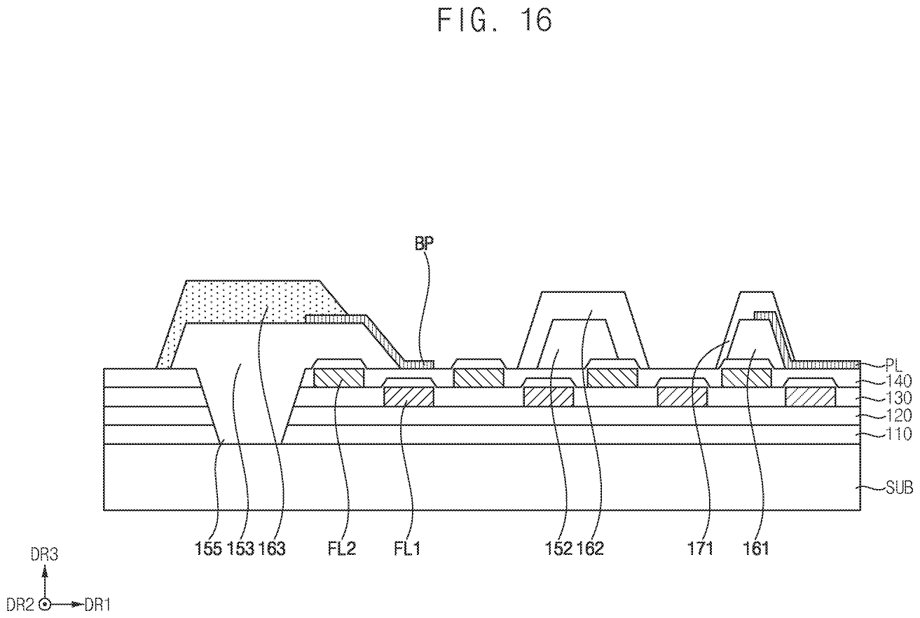

Referring to FIG. 16, the second organic layer 163 may be located on the blocking pattern BP. For example, the blocking pattern BP may be positioned between the first organic layer 153 and the second organic layer 163 along the first side 154 of the first organic layer 153 facing the first dam DM1.

After the manufacturing process of FIGS. 14, 15, and 16, a portion of the first organic layer 153, a portion of the second organic layer 163, the blocking pattern BP, the first dam DM1, and the interlayer insulating layer 140 may be covered.

Accordingly, the display device 100 in FIG. 6 may be manufactured.

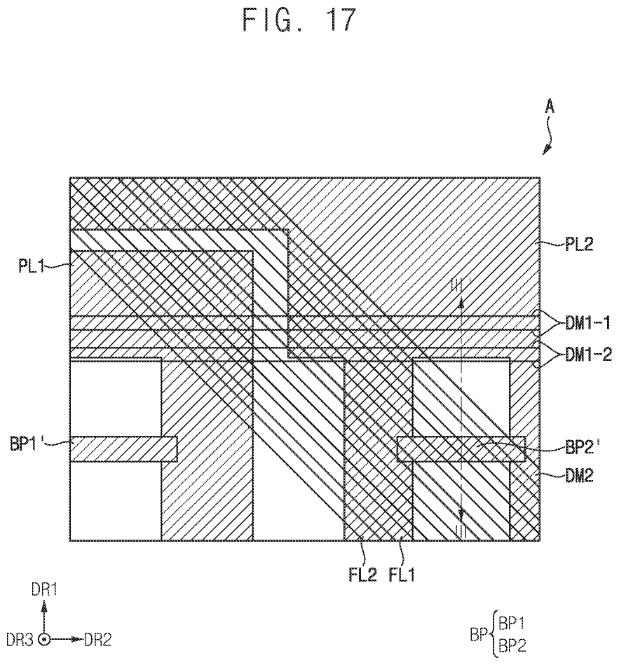

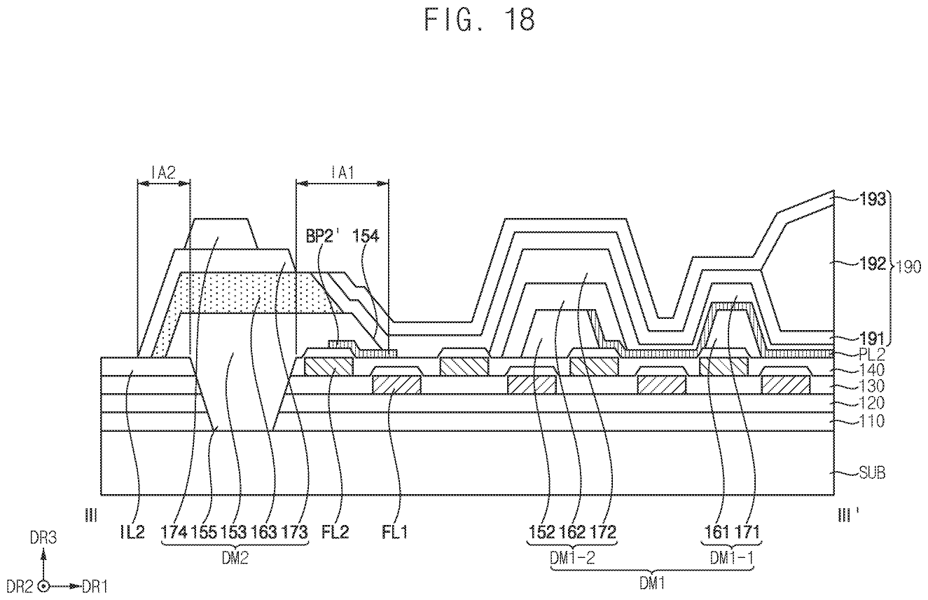

FIG. 17 is an enlarged plan view of area “A” of FIG. 1 according to one or more other embodiments of the present disclosure. FIG. 18 is a cross-sectional view taken along the line III-III′ in FIG. 17.

Hereinafter, descriptions that overlap with the components of the display device 100 described with reference to FIGS. 4, 5, 6, 7, and 8 will be omitted or simplified.

Referring to FIGS. 17 and 18, the first blocking pattern BP1′ may be connected to the first power line PL1, and may be located on a different layer from the first power line PL1. In addition, the second blocking pattern BP2′ may be connected to the second power line PL2, and may be located on a different layer from the second power line PL2.

For example, as shown in FIG. 18, the second blocking pattern BP2′ may be located on the same layer as the first power line PL1 and connected to the second power line PL2. For example, the second blocking pattern BP2′ may contact a lower portion of the first organic layer 153 from the edge of the second dam DM2 facing the first dam DM1, along the interlayer insulating layer 140. In this case, the second blocking pattern BP2′ may not contact the second organic layer 163.

In one or more embodiments, the first blocking pattern BP1′ may be located on the same layer as the second power line PL2, and may contact the first organic layer 153 and the second organic layer 163. For example, the first blocking pattern BP1′ may contact the second organic layer 163 along the first side 154 of the first organic layer 153.

The display device and the method of manufacturing the same according to the embodiments may be applied to a display device included in a computer, a notebook, a mobile phone, a smartphone, a smart pad, a PMP, a PDA, an MP3 player, or the like.

Although the display device and the method of manufacturing the same according to the embodiments have been described with reference to the drawings, the illustrated embodiments are examples, and may be modified and changed by a person having ordinary knowledge in the relevant technical field without departing from the technical spirit described in the following claims, with functional equivalents thereof to be included therein.

What is claimed is:

1. A display device comprising:
a substrate comprising a display area, and a non-display area adjacent to the display area;
a first dam in the non-display area above the substrate; and
a second dam in the non-display area above the substrate, more adjacent to an edge of the non-display area than the first dam, and comprising:
a first organic layer above the substrate; and
a second organic layer above the first organic layer, and spaced from a first side of the first organic layer facing the first dam.

2. The display device of claim 1, wherein the first side of the first organic layer and a side of the second organic layer facing the first dam have a stepped shape.

3. The display device of claim 1, wherein the second organic layer contacts a second side of the first organic layer opposite the first side.

4. The display device of claim 1, further comprising an insulating structure between the substrate and the first dam, and comprising:
a first area contacting the first organic layer, and spaced from the second organic layer; and
a second area contacting the first organic layer and the second organic layer.

5. The display device of claim 4, wherein an opening is defined in the insulating structure to expose at least a portion of an upper surface of the substrate, and
wherein the first organic layer fills the opening.

6. The display device of claim 1, further comprising a blocking pattern between the first organic layer and the second organic layer, and protruding from the second dam toward the first dam.

7. The display device of claim 6, wherein the blocking pattern is at an edge of the second dam, and extends along the first side of the first organic layer.

8. The display device of claim 6, further comprising:
a first power line on the substrate, and overlapping the non-display area; and
a second power line on the substrate, overlapping the non-display area, and spaced from the first power line.

9. The display device of claim 8, wherein the blocking pattern comprises:
a first blocking pattern connected to the first power line, and on a same layer as the first power line; and
a second blocking pattern connected to the second power line, and on a same layer as the second power line.

10. The display device of claim 8, wherein the blocking pattern comprises:
a first blocking pattern connected to the first power line, and on a different layer from the first power line; and
a second blocking pattern connected to the second power line, and on a different layer from the second power line.

11. The display device of claim 8, wherein a low power voltage is applied to the first power line, and
wherein a high-power voltage is applied to the second power line.

12. The display device of claim 6, further comprising:
a transistor in the display area, and comprising:
an active layer above the substrate;
a gate electrode above the active layer; and
a source electrode and a drain electrode contacting the active layer; and
a connection electrode above the transistor, and connected to the transistor.

13. The display device of claim 12, wherein the blocking pattern comprises a same material as the connection electrode.

14. The display device of claim 1, further comprising:
a first inorganic encapsulation layer on the first dam, and extending to the first side of the first organic layer; and
a second inorganic encapsulation layer on the first inorganic encapsulation layer.

15. The display device of claim 14, wherein the first inorganic encapsulation layer contacts the second organic layer.

16. The display device of claim 14, wherein the first inorganic encapsulation layer is spaced from the second organic layer.

17. A method of manufacturing a display device, the method comprising:
forming a first dam in a non-display area on a substrate comprising a display area, and the non-display area adjacent to the display area;
forming a first organic layer in the non-display area, and more adjacent to an edge of the non-display area that the first dam;
forming a second organic layer on the first organic layer, and spaced from a first side of the first organic layer facing the first dam; and
forming a second dam comprising the first organic layer and the second organic layer.

18. The method of claim 17, wherein the first side of the first organic layer and a side of the second organic layer facing the first dam have a stepped shape.

19. The method of claim 17, further comprising forming a blocking pattern between the first organic layer and the second organic layer and protruding from the second dam toward the first dam.

20. The method of claim 17, further comprising:
forming a first inorganic encapsulation layer on the first dam and extending to the first side of the first organic layer; and
forming a second inorganic encapsulation layer on the first inorganic encapsulation layer.
